(19) United States
(12) Patent Application Publication
(10) Pub. No.: US 2013/0161612 A1
(43) Pub. Date: Jun. 27, 2013

(54) DISPLAY DEVICE AND IMAGE DISPLAY SYSTEM EMPLOYING THE SAME

(71) Applicants: INNOCOM TECHNOLOGY (SHENZHEN) CO., LTD., Shenzhen City (CN); CHIMEI INNOLUX CORPORATION, Chu-Nan (TW)

(72) Inventors: Ramesh KAKKAD, Chu-Nan (TW); Ching-Chao CHANG, Chu-Nan (TW)

(73) Assignees: CHIMEI INNOLUX CORPORATION, Chu-Nan (TW); INNOCOM TECHNOLOGY (SHENZHEN) CO., LTD., Shenzhen City (CN)

(21) Appl. No.: 13/728,547

(22) Filed: Dec. 27, 2012

(30) Foreign Application Priority Data
Dec. 27, 2011 (TW) 100148817

(51) Int. Cl. H01L 27/13

(52) U.S. Cl. CPC H01L 27/13
USPC 257/43

(57) ABSTRACT

A display device and an image display system employing the same are provided. The display device includes a thin film transistor and a storage capacitor. The thin film transistor includes a channel. The storage capacitor includes a transparent metal electrode made of the same material as the channel, and a pixel electrode disposed on the transparent metal electrode electrically connected to the thin film transistor.

### CROSS REFERENCE TO RELATED APPLICATIONS

This application is based upon and claims the benefit of priority from the prior Taiwan Patent Application No. 100148817, filed on Dec. 27, 2011, the entire contents of which are incorporated herein by reference.

### BACKGROUND

1. Technical Field

The invention relates to a display device and an image display system employing the same and more particularly to a display device with a high aperture ratio and an image display system employing the same.

2. Description of the Related Art

Generally, a pixel substrate of a thin film transistor display device includes transistors, storage capacitors, pixel electrodes, scan lines, and data lines. Particularly, the storage capacitor maintains the voltage for driving the liquid crystal, avoiding the phenomenon of unsightly flickering and improving the color contrast.

FIG. 1 shows a cross section of a pixel substrate 50 of the conventional liquid display device with a bottom gate type thin film transistor. The pixel substrate 50 includes a substrate 10. A gate electrode 14 and a common line 12 are formed on the substrate 10.

A gate insulator 16 is formed on the gate electrode 14 and the common line 12. A channel 18 is disposed on the gate insulator 16 directly over the gate electrode. Source/drain electrodes 20 are formed respectively at the two sides of the channel 18, and a metal contact layer 22 is formed on the gate insulator 16. A passivation layer 24 is conformally formed on the source/drain electrodes 20, the channel 18, and the metal contact layer 22. A via 26 passes through the passivation layer 24, exposing a part of the top surface of the metal contact layer 22; and a transparent conductive layer 28 (serving as pixel electrode) is formed on the passivation layer 24 directly over the common line and filled into the via 26 to directly make contact with the metal contact layer 22. Still referring to FIG. 1, the common line 12, a part of the transparent conductive layer 28, and the gate insulator 16 and the passivation layer 24 disposed between the common line 12 and the transparent conductive layer 28 formed a storage capacitor, wherein the common line 12 serves as a bottom electrode of the storage capacitor, and the transparent conductive layer 28 serves as the top electrode of the storage capacitor. In general, in order to reduce the photolithography process steps used in the fabrication of the pixel substrate 50 (the method for fabricating the pixel substrate 50 employs five photolithography processes), the gate electrode 14 and the common line 12 are formed simultaneously by patterning a first metal conductive layer via a photolithography process. Namely, the common line 12 and the gate electrode 14 are made of an opaque metal conductive layer. The light emitted by the backlight source, however, cannot pass through the storage capacitor 30, reducing the aperture ratio and brightness of display device. Further, with the increasing resolution of LCDs, it has become important to increase the aperture ratio of each pixel for improved performance. To increase the aperture ratio, the plane area of the storage capacitor must be reduced, and the occupied area of pixel electrodes must be enlarged as much as possible. Nevertheless, as resolution increases, requirements for reducing the pixel size and plane area of the storage capacitor result in problems such as flickering, low color contrast and cross-talk.

Therefore, a new structure capable of increasing storage capacitance without sacrificing the aperture ratio of a pixel, or maintaining the storage capacitance while increasing the aperture ratio of a pixel is desirable.

### SUMMARY

The invention provides a display device with a high aperture ratio and an image display system employing the same. The display device has a transparent bottom electrode of the storage capacitor, thereby increasing the aperture ratio of the pixel region on the premise that the numbers of photolithography processes used in the fabrication process are not increased.

An exemplary embodiment of the invention provides a display device including a thin film transistor and a storage capacitor. Particularly, the thin film transistor has a channel, and the storage capacitor comprises a transparent metal electrode and a pixel electrode, wherein the transparent metal electrode is made of as the same material as the channel. The pixel electrode is disposed on the transparent metal electrode, electrically connected to the thin film transistor.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 is a schematic cross section of a conventional pixel substrate.

FIG. 2 is a schematic cross section of the display device according to an embodiment of the present invention.

FIGS. 3a-3i are a series of schematic cross sections showing the method for fabricating the display device as shown in FIG. 2.

FIG. 4 is a schematic cross section of the display device according to another embodiment of the present invention.

FIGS. 5a-5c are a series of schematic cross sections showing the method for fabricating the display device according to another embodiment of the present invention.

FIGS. 6a-6d are a series of schematic cross sections showing the method for fabricating the display device according to yet another embodiment of the present invention.

FIG. 7 schematically shows an image display system including the display device of the invention.

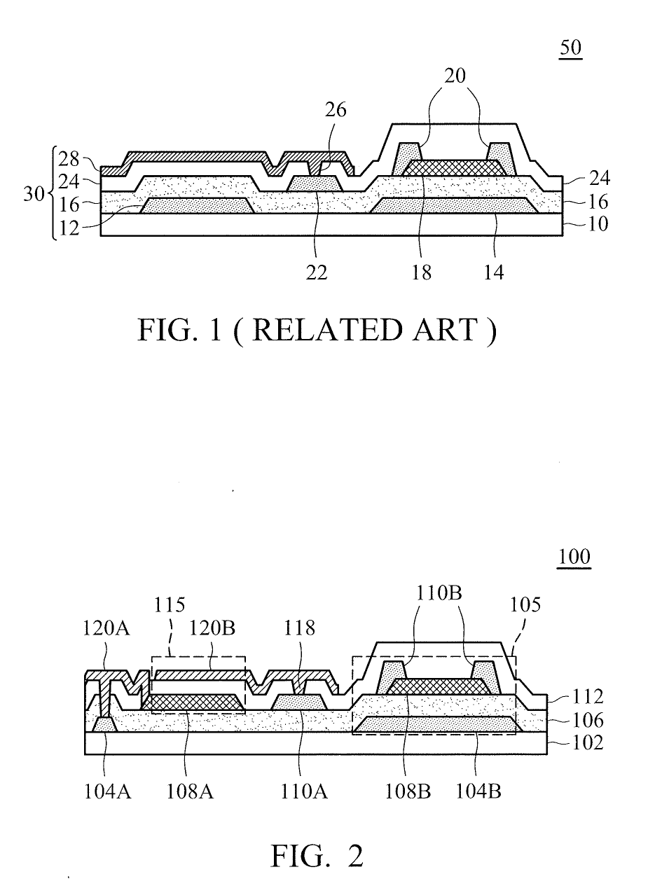

### DETAILED DESCRIPTION

The following description is of the best-contemplated mode of carrying out the invention. This description is made for the purpose of illustrating the general principles of the invention and should not be taken in a limiting sense. The scope of the invention is best determined by reference to the appended claims.

As shown in FIG. 2, a display device 100 with high aperture ratio according to an embodiment of the invention is provided. The display device 100 includes a substrate 102, wherein the substrate 102 can be a transparent or opaque substrate, such a glass substrate, a ceramic substrate, or a plastic substrate. A first contact 104A, and a gate electrode 104B are disposed on a top surface of the substrate 102, wherein the first contact 104A is made of as the same material as the gate electrode 104B. Namely, the first contact 104A and the gate electrode 104B are formed simultaneously by patterning a first metal conductive layer (not shown, i.e. metal one (M1)) via a photolithography process. The first metal conductive layer can include a conductive metal, such as Mo, W, Al, Ti, Cr or combinations thereof. In comparison with conventional display device,

since the first contact 104A is used to provide a common potential (Vcom) for a bottom electrode of a subsequently formed storage capacitor rather than serving as the bottom electrode of a subsequently formed storage capacitor, the first contact 104A can be formed outside the pixel region of the display device 100, avoiding a reduction in the aperture ratio. A gate insulator 106 is disposed on the substrate 102, covering the gate electrode 104B, and the first contact 104A. Suitable materials of the gate insulator 106 can be dielectric material, such as silicon oxide or silicon nitride. A transparent metal electrode 108A is disposed on the gate insulator 106 within the pixel region of the display device 100, and a channel 108B is disposed on the gate insulator 106 directly over the gate electrode 104B, wherein the transparent metal electrode 108A is made of as the same material as the channel 108B. Namely, the transparent metal electrode 108A and the channel 108B are formed simultaneously by patterning a transparent metal oxide layer (not shown) via a photolithography process.

It should be noted that, in the conventional display device, since the bottom electrode of the storage capacitor within the pixel region and the gate electrode are formed simultaneously by patterning an opaque metal material layer, the aperture ratio of the pixel region is reduced due to the opaque bottom electrode of the storage capacitor. In the invention, the transparent metal electrode 108A serves as the bottom electrode of the storage capacitor. Since the transparent metal electrode 108A is made of a transparent and conductive metal oxide (such as indium tin oxide (ITO), indium zinc oxide (IZO), indium tin zinc oxide (ITZO), aluminum zinc oxide (ZAO), gallium zinc oxide (GZO), or combinations thereof), the light emitted by the backlight source would not be shielded by the transparent metal electrode 108A. Therefore, the aperture ratio would not be reduced, even increasing the area occupied by the storage capacitor.

Further, the transparent metal electrode 108A and the channel 108B are formed by patterning a transparent metal oxide layer via a photolithography process (i.e. the transparent metal electrode 108A [serving as the bottom electrode of the storage capacitor] and the channel 108B of the thin film transistor 105 are formed simultaneously through the same process), rather than forming an additional transparent conductive layer and then patterning the additional transparent conductive layer by an additional photolithography process. Therefore, the process complexity of the display device can be reduced.

Source/drain electrodes 110B are formed on the gate insulator 106 disposed at two sides of the channel 108B, electrically contacting the channel 108B. A second contact 110A is disposed on the gate insulator 106, wherein the source/drain electrodes 110B are made of the same material as the second contact 110A. Namely, the source/drain electrodes 110B and the second contact 110A are formed simultaneously by patterning a second metal conductive layer (not shown, i.e. metal two [M2]) via a photolithography process. Suitable materials of the second metal conductive layer can be conductive metal, such as Mo, W, Al, Ti, Cr, or combinations thereof.

The gate electrode 104B, the channel 108B, the source/drain electrodes 110B, and the gate insulator 106 disposed between the gate electrode 104B and the channel 108B formed a thin film transistor 105, and the second contact 110A is used to electrically contact a subsequently formed pixel electrode. A passivation layer 112 is disposed on the gate insulator 106, covering the transparent metal electrode 108A, the second contact 110A, the source/drain electrodes 110B, and the channel 108B. Suitable materials of the passivation layer 112 can be dielectric materials, such as silicon oxide or silicon nitride.

A first contact hole 114 passes through the gate insulator 106 and the passivation layer 112, exposing a part of the first contact 104A. A second contact hole 116 passes through the passivation layer 112, exposing a part of the transparent metal electrode 108A. A third contact hole 118 passes through the passivation layer 112, exposing a part of the second contact 110A. Particularly, the first contact hole 114, second contact hole 116, and third contact hole 118 are formed by patterning the passivation layer 112 via a photolithography process.

A transparent connecting layer 120A is disposed on the passivation layer 112 and filled into the first contact hole 114 and the second contact hole 116, electrically connecting to the first contact 104A and the transparent metal electrode 108A. A pixel electrode 120B is disposed on the passivation layer 112 directly over the transparent metal electrode 108 and filled into the third contact hole 118, electrically connecting to the second contact 110A, wherein the transparent connecting layer 120A is made of as the same material as the pixel electrode 120B. Namely, the transparent connecting layer 120A and the pixel electrode 120B are formed simultaneously by patterning a transparent conductive layer (not shown) via a photolithography process. Suitable materials of the transparent conductive layer can be metal oxide, such as indium tin oxide (ITO), indium zinc oxide (IZO), indium tin zinc oxide (ITZO), aluminum zinc oxide (ZAO), gallium zinc oxide (GZO), or combinations thereof. It should be noted that the pixel electrode 120B, the transparent metal electrode 108A, and the passivation layer 112 disposed between the transparent metal electrode 108A and the pixel electrode 120B comprise a storage capacitor 115, wherein the pixel electrode 120B serves as the top electrode of the storage capacitor 115, and the passivation layer 112 between the transparent metal electrode 108A and the pixel electrode 120B serves as the capacitor dielectric layer of the storage capacitor 115. Accordingly, the display device 100 can be fabricated by a method merely employing five photolithography processes. In comparison with the conventional display device, the aperture ratio of the display device 100 can be increased on the premise that the numbers of photolithography process used in the fabrication process are not increased.

Further, according to an embodiment of the invention, since the transparent metal electrode 108A is a transparent conductive layer and is disposed directly below the pixel electrode 120B, and the transparent metal electrode 108A and the pixel electrode 120B can be comb-shaped and can comprise a fringe-field switching mode electrode array structure, the view angle of the display device is increased.

Moreover, according to some embodiments of the invention, the first contact hole 114 and the second contact hole 116 can comprise a single via, passing through the gate insulator 106 and the passivation layer 112 and exposing a part of the transparent metal electrode 108A and a part of the first contact 104A. The transparent connecting layer 120A is filled into the via, electrically connecting to the first contact 104A and the transparent metal electrode 108A.

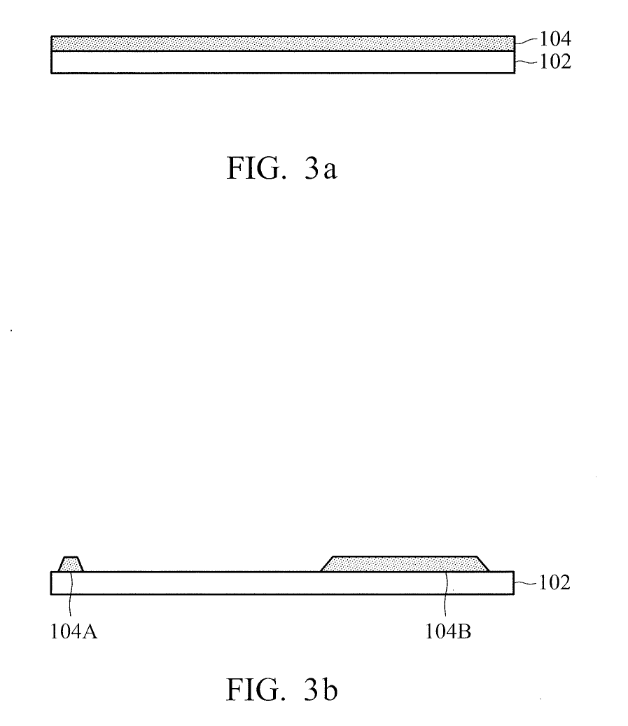

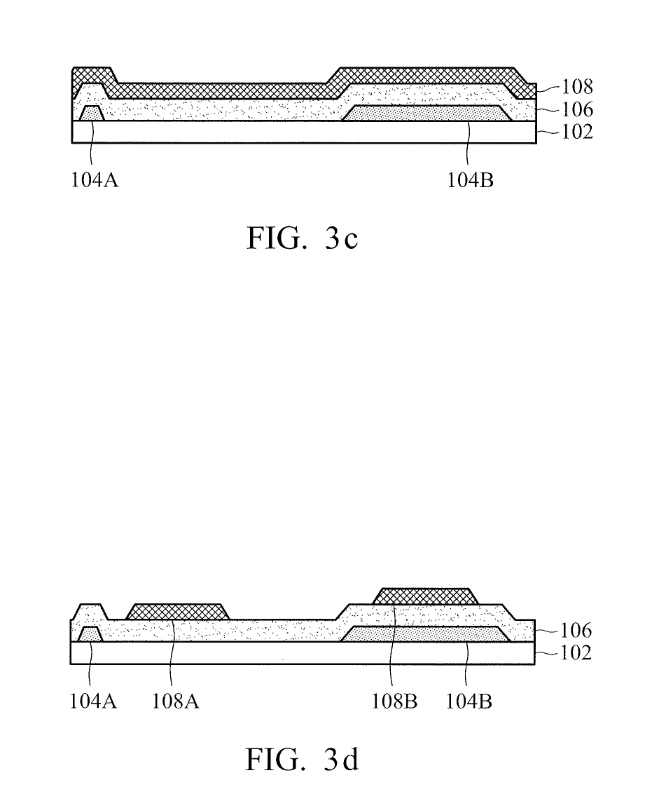

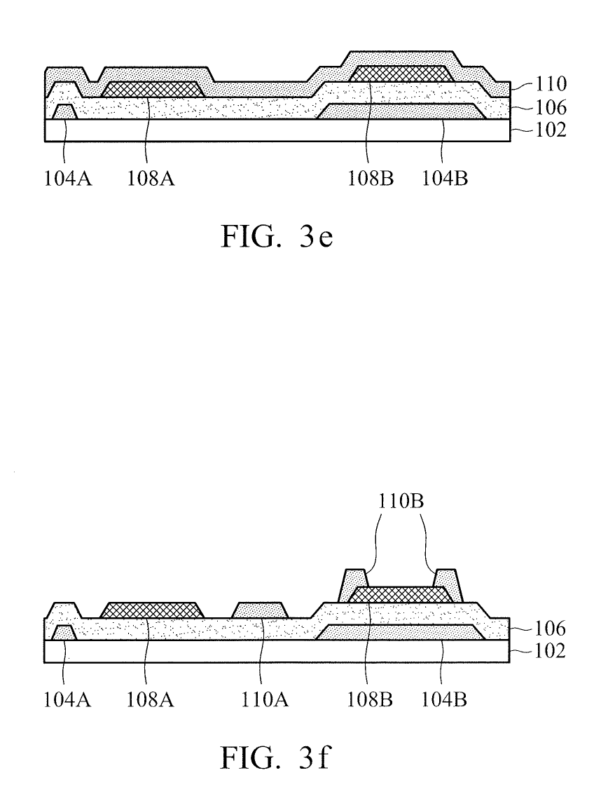

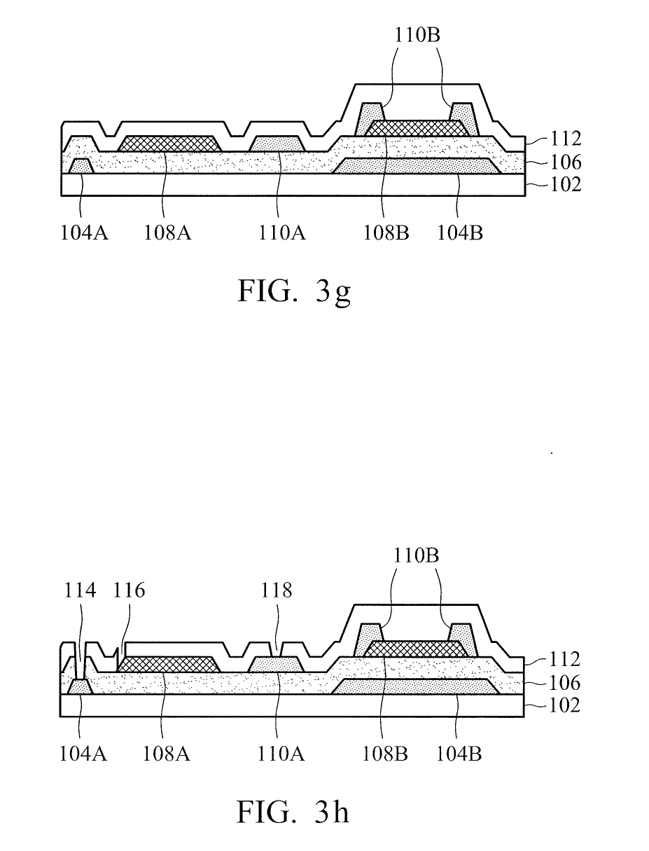

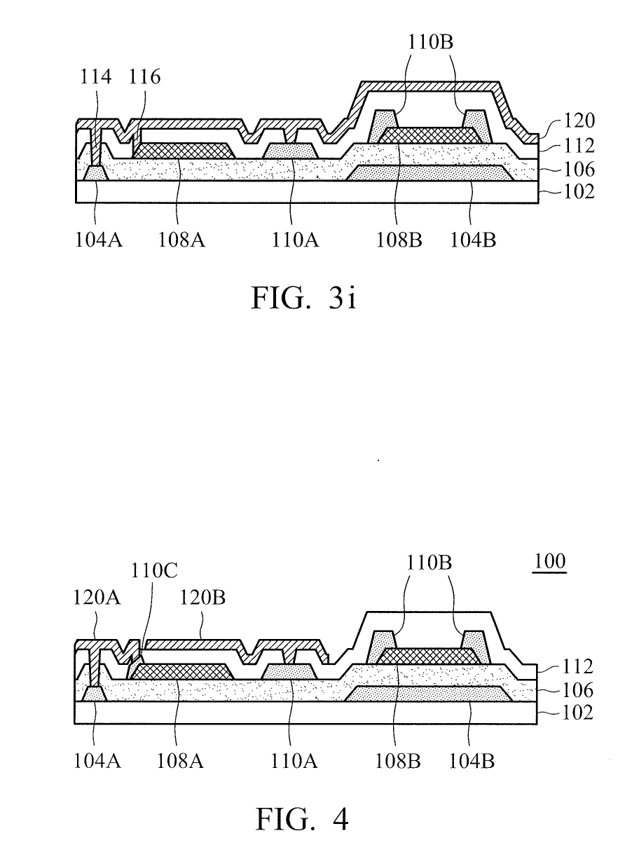

FIGS. 3a to 3i are a series of cross sections showing the fabrication method of the display device 100 shown in FIG. 2. Herein, although the thin film transistor of the display device is a bottom gate type thin film transistor, the thin film transistor of the display device can also be a top gate type thin film transistor according to some embodiments of the invention. First, as shown in FIG. 3a, a substrate 102 is provided, and a first metal conductive layer 104 (opaque conductive layer) is formed on the substrate 102. Next, as shown in FIG. 3b, the first metal conductive layer 104 is patterned by a first photolithography process, obtaining a first contact 104A, and gate electrode 104B. Namely, the first contact 104A, and gate electrode 104B are formed simultaneously of the same material through the same process. Next, as shown in FIG. 3c, a gate insulator 106 is conformally formed on the substrate 102, covering the gate insulator 106. After forming the gate insulator 106, a transparent metal oxide layer 108 is conformally formed on the gate insulator 106. Next, as shown in FIG. 3d, the transparent metal oxide layer 108 is patterned by a second photolithography process, forming a transparent metal electrode 108A (within the pixel region) and a channel 108B (disposed on the gate electrode 104B). Namely, the transparent metal electrode 108A and channel 108B are formed simultaneously of the same material through the same process. It should be noted that, in the second photolithography process, the transparent metal oxide layer 108 (and an etching stop layer [not shown] disposed on the etching stop layer 108) can be patterned by a back-channel-etched with the gate electrode 104B as mask.

Next, as shown in FIG. 3e, a second metal conductive layer 110 is conformally formed on the gate insulator 106, covering the transparent metal electrode 108A and channel 108B. Next, as shown in FIG. 3f, the second metal conductive layer 110 is patterned by a third photolithography process, forming a second contact 110A and source/drain electrodes 110B (disposed on the second metal conductive layer 110 at two sides of the channel 108B), wherein the source/drain electrodes 110B make contact with the channel 108B. Namely, the second contact 110A and source/drain electrodes 110B are formed simultaneously of the same material through the same process. Next, as shown in FIG. 3g, a passivation layer 112 is conformally formed at the gate insulator 106, covering the transparent metal electrode 108A, the second contact 110A, the source/drain electrodes 110B, and the channel 108B. Next, as shown in FIG. 3h, the passivation layer 112 is patterned by a fourth photolithography process, forming a first contact hole 114, a second contact hole 116, and a third contact hole 118. Particularly, the first contact hole 114 passes through the gate insulator 106 and the passivation layer 112, exposing a part of the first contact 104A; the second contact hole 116 passes through the passivation layer 112, exposing a part of the transparent metal electrode 108A; and the third contact hole 118 passes through the passivation layer 112, exposing a part of the second contact 110A. Next, as shown in FIG. 3i, a transparent conductive layer 120 is conformally formed on the passivation layer 112 and filled into the first contact hole 114, the second contact hole 116, and the third contact hole 118.

Finally, the transparent conductive layer 120 is patterned by a fifth photolithography process, forming a transparent connecting layer 120A and pixel electrode 120B. Namely, the transparent connecting layer 120A and pixel electrode 120B are formed simultaneously of the same material through the same process. The transparent connecting layer 120A is disposed on the passivation layer 112 and filled into the first contact hole 114 and the second contact hole 116, resulting in the first contact 104A and the transparent metal electrode 108A being electrically connected to each other via the transparent connecting layer 120A. The pixel electrode 120B is disposed on the passivation layer 112 directly over the transparent metal electrode 108A and filled into the third contact hole 118, electrically connecting to the second contact 110A, obtaining the display device 100 as shown in FIG. 2.

According to an embodiment of the invention, after forming the second metal conductive layer 110 on the gate insulator 106 as shown in FIG. 3e, the second metal conductive layer 110 can be patterned to form a second contact 110A, the source/drain electrodes 110B, and a third contact 110C (i.e. the second contact 110A, source/drain electrodes 110B, and third contact 110C are formed simultaneously of the same material through the same process). Particularly, the third contact 110C directly contacts the transparent metal electrode 108A. As shown in FIG. 4, the third contact 110C can improve the electrical conductivity between the transparent connecting layer 120A and source/drain electrodes 110B, thereby reducing the resistance between the transparent connecting layer 120A and source/drain electrodes 110B.

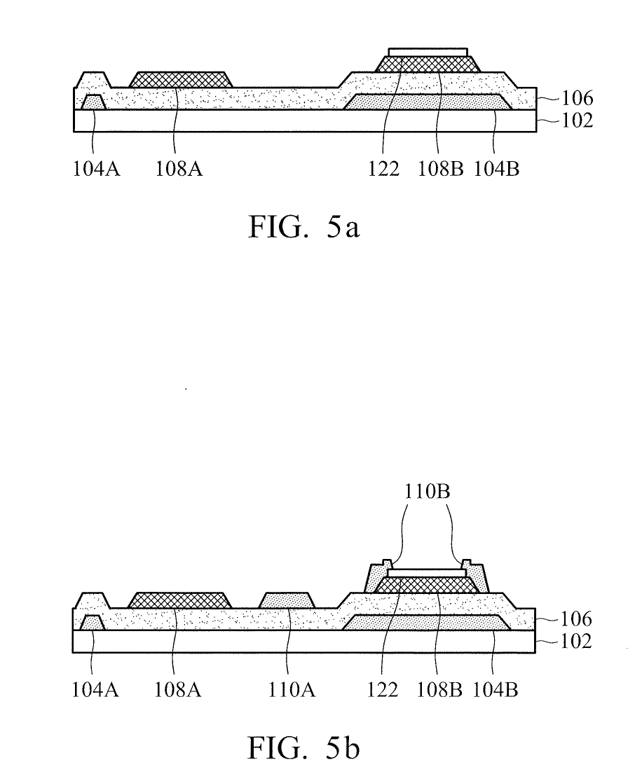

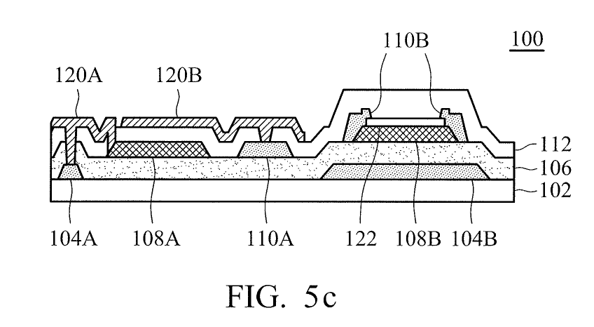

Further, according to some embodiments of the invention, the exposure step of the second photolithography process can be performed to form the substrate 102 side (using the gate electrode 104B as mask), forming the transparent metal electrode 108A and channel 108B. As shown in FIG. 5a, in order to prevent damage from removing the second metal conductive layer 110 formed on the channel 108B, an etching stop layer 122 can be formed on the channel 108B by a sixth photolithography process before forming the second metal conductive layer 110. Next, as shown in FIG. 5b, after patterning the second metal conductive layer 108, the second contact 110A and source/drain electrodes 110B are formed. Next, after performing the steps shown in FIGS. 3g and 3i, a display device 100 shown in FIG. 5c is obtained.

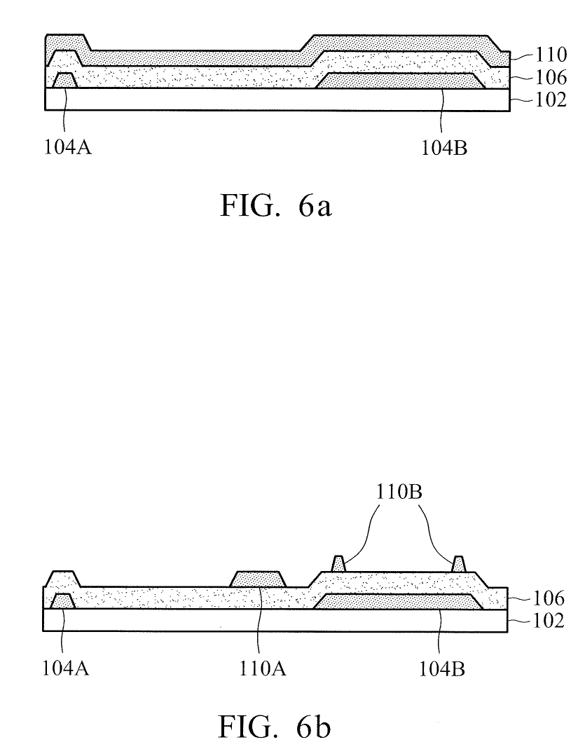

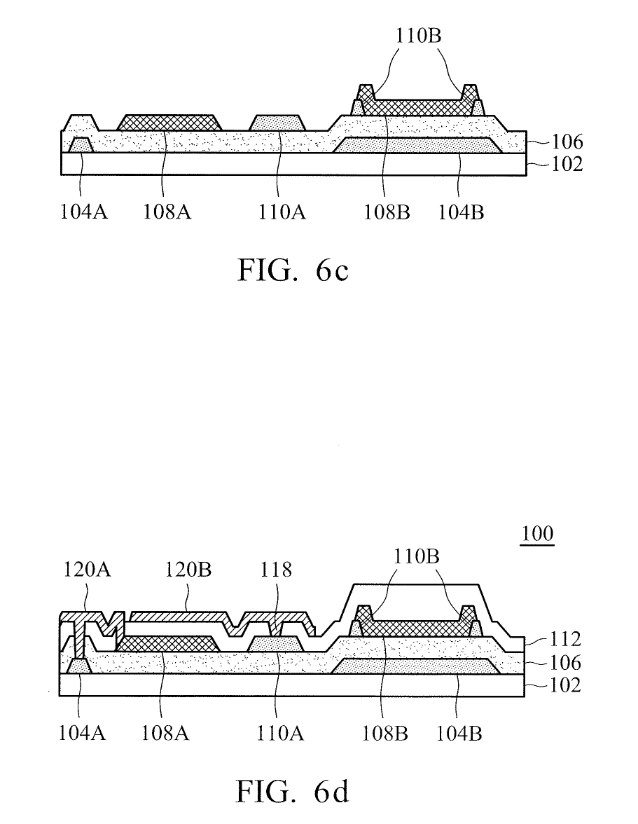

Moreover, according to some embodiments of the invention, in order to prevent channel 108B from damage during patterning the second metal conductive layer 110, the second contact 110A and source/drain electrodes 110B can be formed by patterning the second metal conductive layer 110 before forming the channel 108B. As shown in FIG. 6a, the second metal conductive layer 110 is formed on the gate insulator 106. Next, the second metal conductive layer 110 is patterned to form a second contact 110A and source/drain electrodes 110B, as shown in FIG. 6b. Next, the transparent metal oxide layer 108 is formed and patterned to form the transparent metal oxide electrode 108A and channel 108B, as shown in FIG. 6c. Particularly, the channel 108B is formed between the source/drain electrodes 110B, contacting the source/drain electrodes 110B. Next, after performing the steps shown in FIGS. 3g and 3i, a display device 100 shown in FIG. 5d is obtained.

Accordingly, since the bottom electrode of the storage capacitor is made of transparent oxide, the aperture ratio of the display device of the invention would not be reduced even increasing the area occupied by the storage capacitor. Further, since the transparent bottom electrode of the storage capacitor and the channel are formed of the same material through the same process, there is no additional photolithography process which is employed to form the transparent bottom electrode, thereby reducing the process complexity of the display device. Moreover, the bottom electrode of the storage capacitor and the common line (i.e. the first contact) are electrically connected to each other via a transparent connecting layer. Since the transparent connecting layer is formed by the same process that forms the pixel electrode, there is no additional photolithography process which is employed to form the transparent connecting layer. In comparison with the conventional display device, the aperture ratio of the display device of the invention can be improved on the premise that the numbers of photolithography processes used in the fabrication process are not increased and the common driving design can be maintained.

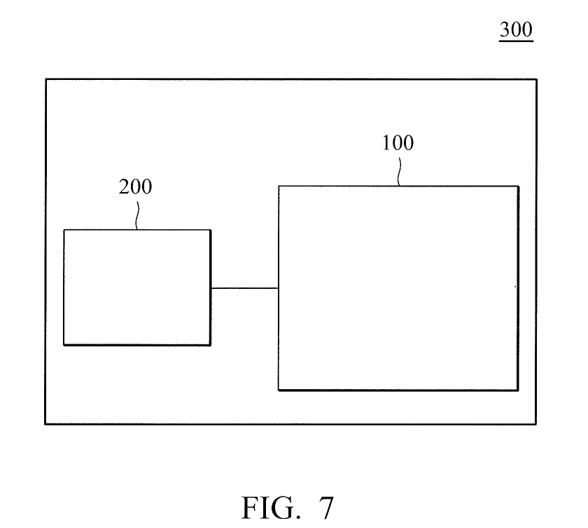

Referring to FIG. 7, an image display system 300 for displaying images including the display device 100 according to an embodiment of the invention is shown. The image display system 300 can be an electrical device such as notebook computer, mobile phone, digital camera, personal data assistant (PDA), desktop computer, television, car display, or portable DVD player. The display device 100 of the image display system 300 can be further coupled to an input unit 200. The input unit 200 is operative to provide input to the display device 100, such that the display device 100 displays images.

While the disclosure has been described by way of example and in terms of the preferred embodiments, it is to be understood that the disclosure is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A display device, comprising:
a thin film transistor having a channel; and
a storage capacitor comprising:
a transparent metal electrode, wherein the transparent metal electrode is made of as the same material as the channel; and
a pixel electrode, disposed on the transparent metal electrode, electrically connecting to the thin film transistor.

2. The display device as claimed in claim 1, wherein the transparent metal electrode and the channel are disposed on the same layer.

3. The display device as claimed in claim 1, wherein the transparent metal electrode and the channel are simultaneously formed by patterning a transparent metal oxide layer via a photolithography process.

4. The display device as claimed in claim 1, wherein the transparent metal oxide layer comprises indium tin oxide, indium zinc oxide, indium tin zinc oxide, aluminum zinc oxide, gallium zinc oxide, or combinations thereof.

5. The display device as claimed in claim 1, wherein the display device further comprises a first contact, the first contact electrically connects to the transparent metal electrode.

6. The display device as claimed in claim 5, wherein the thin film transistor further comprises a gate electrode, and the gate electrode is made of as the same material as the first contact.

7. The display device as claimed in claim 6, wherein the gate electrode and the first contact are disposed on the same layer.

8. The display device as claimed in claim 6, wherein the gate electrode and the first contact are formed simultaneously by patterning a transparent metal oxide layer via a photolithography process.

9. The display device as claimed in claim 1, wherein the pixel electrode is comb-shaped, and the pixel electrode and the transparent metal electrode comprise a fringe-field switching mode electrode array structure.

10. An image display system, including:
the display device as claimed in claim 1; and
an input unit coupled to the display device and operative to provide input to the display device such that the display device displays images

11. The image display system as claimed in claim 10, wherein the image display system comprises a notebook computer, mobile phone, digital camera, personal data assistant, desktop computer, television, car display, or portable digital video disc player.
